(19) United States
(12) Patent Application Publication
(10) Pub. No.: US 2026/0255504 A1
(43) Pub. Date: Aug. 27, 2026

(54) ELECTRONIC HOUSING

(71) Applicant: PHOENIX CONTACT GMBH & CO. KG, Blomberg (DE)

(72) Inventors: Helmut EUSTERHOLZ, Paderborn (DE); Lisa PICHERER, Blomberg (DE)

(21) Appl. No.: 18/857,476

(22) PCT Filed: Apr. 12, 2023
(86) PCT No.: PCT/EP2023/059518

§ 371 Date: Nov. 19, 2024

(30) Foreign Application Priority Data
Apr. 19, 2022 (LU) LU501858

(51) Int. Cl. H05K 5/00; H05K 5/06

(52) U.S. Cl. CPC H05K 5/006; H05K 5/0052; H05K 5/06

(57) ABSTRACT

An electronics housing for receiving a printed circuit board includes: a first housing part; and a second housing part. The first and second housing parts are joinable together along a joint edge in a form-fitting and separable manner, and the first and second housing parts have lateral walls that adjoin one another at edges and form a housing shell. A first lateral wall of the first housing part is lower than a second lateral wall of the first housing part in at least one region, the second lateral wall lying opposite the first lateral wall, in order to insert the printed circuit board into the first housing part via the first lateral wall. The second lateral wall has at least one opening for introducing a connection element connected to the printed circuit board into the at least one opening.

### CROSS-REFERENCE TO PRIOR APPLICATIONS

This application is a U.S. National Phase application under 35 U.S.C. § 371 of International Application No. PCT/EP2023/059518, filed on Apr. 12, 2023, and claims benefit to Luxembourg Patent Application No. LU 501858, filed on Apr. 19, 2022. The International Application was published in German on Oct. 26, 2023 as WO/2023/202923 under PCT Article 21(2).

### FIELD

The invention relates to an electronics housing for receiving a printed circuit board and a system having an electronics housing and a printed circuit board.

### BACKGROUND

Such electronics housings comprise a first housing part and a second housing part, wherein the housing parts can be joined together along a joint edge in a form-fitting and separable manner, and the housing parts have lateral walls that adjoin one another at the edges and form a housing shell.

The electronics housings known from the prior art are used, for example, for machine controllers, controllers in vehicles, in heating and air conditioning technology, etc. In this case, printed circuit boards for embedded systems or single-board computers are often inserted into the first housing part and connection elements that are connected to the printed circuit board are led through openings in the housing parts. Depending on the application, the housings are often designed according to an IP (Ingress Protection) protection class to protect the printed circuit board from external influences such as dust or moisture. For example, the document US 2019/0289728 A1 shows an electronics housing known from the prior art.

However, the electronics housings known from the prior art have the disadvantage that the printed circuit board must be inserted through an open side, for example in an assembly direction from above, toward a base surface of one of the often shell-shaped housing parts in order to then be fastened therein. Mounting printed circuit boards with connection elements that protrude beyond an edge of the printed circuit board and, in the mounted state, have to be guided through an opening in the housing parts is often difficult or even impossible.

Due to the design, the opening for the connection element often extends between the housing parts, which makes it difficult to efficiently seal the interior of the electronics housing against external influences. Also, in many of the electronics housing types known from the prior art, the connection element cannot be inserted into the electronics housing at the same time as the printed circuit board and must therefore be fastened to the printed circuit board after being introduced into the opening provided for this purpose in the material of the electronics housing.

### SUMMARY

In an embodiment, the present invention provides an electronics housing for receiving a printed circuit board, comprising: a first housing part; and a second housing part, wherein the first and second housing parts are joinable together along a joint edge in a form-fitting and separable manner, and the first and second housing parts have lateral walls that adjoin one another at edges and form a housing shell, wherein a first lateral wall of the first housing part is lower than a second lateral wall of the first housing part in at least one region, the second lateral wall lying opposite the first lateral wall, to insert the printed circuit board into the first housing part via the first lateral wall, and wherein the second lateral wall has at least one opening for introducing a connection element connected to the printed circuit board into the at least one opening.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1A-1C show views of a first housing part and a printed circuit board according to an embodiment of the invention;

FIG. 2A-2E show views of the electronics housing with a printed circuit board arranged therein according to the previously shown embodiment of the invention;

FIGS. 3A, 3B show views of the first and second housing parts and a mounting adapter according to an embodiment of the invention; and

FIGS. 4A, 4B show sectional views through a locking element of the mounting adapter inserted into an elongated hole in the first housing half.

### DETAILED DESCRIPTION

In an embodiment, the present invention provides an electronics housing which allows for a simple introduction of a printed circuit board into the electronics housing and allows for a simple integration of the connection technology connected to the board. In addition, the electronics housing may be assembled quickly, safely and, possibly, automatically.

Accordingly, a first lateral wall of the first housing part in at least one region, said second lateral wall lying opposite the first lateral wall, in order to insert the printed circuit board into the first housing part via the first lateral wall, and the second lateral wall has at least one opening for introducing a connection element connected to the printed circuit board into the opening.

The first and second housing parts can be designed in a shell-like manner and substantially complementary to one another in order to surround a printed circuit board in the assembled state. The term “joint edge” can be understood here as an edge on which the first housing part and the second housing part meet when joined together. The “joint edge” can also be understood as a “joint surface.”

The first housing part and the second housing part have lateral walls that adjoin one another at the edges and form a housing shell. The housing parts can be designed in a shell-like manner and the lateral walls can be arranged transversely, in particular at a right angle, on a corresponding base surface of the housing parts and enclose a volume. The lateral surfaces can extend from the base surface to a free end of the housing parts.

In examples, the base surface can be rectangular. Alternatively, the base surface can also be designed to be polygonal or, in particular in corner regions, in some regions round. The housing walls can also be arranged at an angle of more or less than 90° on the base surface. The joint edge can run along a free end of the lateral walls, wherein the free end also forms an edge for delimiting an interior space of the housing parts.

According to the invention, a first lateral wall of the first housing part is designed to be lower than a second lateral wall of the first housing part in at least one region, opposite the first lateral wall, in order to insert the printed circuit board into the first housing part via the first lateral wall.

The term “lower” can be understood here to mean that a height of the first housing part or at least a region of the first lateral wall from the base surface of the first housing part to the joint edge at the end of the first lateral wall is lower than the height of the second lateral wall from the base surface of the first housing part to the joint edge at the end of the second lateral wall.

The printed circuit board can thus be inserted into the first housing part substantially horizontally to the base surface of the first housing part over the joint edge of the first lateral wall up to the second lateral wall.

Furthermore, the second housing wall has at least one opening, which can be understood as a through opening in the material of the second housing wall and is completely surrounded by the material of the second housing wall. The opening can, for example, be pre-stamped in the material of the second housing hand and pierced to introduce the connection element. Furthermore, the “opening” can also be understood as an opening through which a line for connecting the printed circuit board is guided or formed.

A connection element arranged on the printed circuit board, for example an electrical socket, can thus be introduced into the opening via the first lateral wall when the circuit board is inserted in order to be able to be electrically contacted from outside the electronics housing. In examples, a plurality of connection elements can be arranged on the printed circuit board and each inserted into a corresponding opening in the second lateral wall.

A connection element arranged on the printed circuit board can also be understood, for example, as a connection which is available on the outside of the second housing side after the printed circuit board has been mounted. Via the connection element, the printed circuit board can be connected or is connected to a conductor leading outside the housing. In particular, the conductor can be designed as an electrical conductor or as an optical fiber for the transport of signals or data.

Advantageously, the design of the first housing part described herein allows for an easy assembly and disassembly of the printed circuit board by inserting it into the first housing part. Another advantage of the lateral walls is that their wedge-shaped design provides easy guidance for easy insertion and removal of the printed circuit board. Furthermore, by inserting it, a connection of the printed circuit board to the outside can be advantageously established. Another advantage of the high design of the second lateral wall is that the connection technology is very well sealed, since the opening does not have to extend over two housing parts, but can be inserted exclusively in the material of the first lateral wall.

In one example, the first housing part has fastening means for fastening the printed circuit board in the first housing part.

A fastening means can be understood as a means such as a screw or latching connection, which fixes or positions the printed circuit board in the first housing part so that the printed circuit board can no longer be moved with respect to the first housing part or can only be moved minimally, for example by being mounted in a floating manner. Typically, the printed circuit board is first inserted into the first housing part and then fastened to the fastening means.

In examples, the fastening means has at least one screw dome, means for forming a latching connection for fastening the printed circuit board in the first housing part, or a screw connection for holding the connection element and the circuit board connected thereto in the opening.

For example, screw domes in corner regions of the first housing part can extend from the base surface, parallel to the lateral walls, and regions of the printed circuit board can rest on the screw domes. After the printed circuit board has been introduced, screws can be inserted through the openings provided in the printed circuit board in order to fix the printed circuit board. Advantageously, such a screw connection can establish a particularly durable mechanical connection.

Alternatively or additionally, the printed circuit board can also be held in the first housing part by means of a latching connection. For example, latching hooks or similar latching elements can be provided on the lateral walls to hold the printed circuit board.

Advantageously, such a latching connection can be established and released very quickly.

In a further alternative or in addition to the described embodiments of the fastening means, the fastening means can also have a screw connection which is adapted to fix the connection element inserted into the opening. For example, the screw connection can be screwed onto an external thread of the connection element that protrudes from the opening in order to fix the connection element and the printed circuit board connected thereto. Advantageously, if a screw connection is used as a fastening means, the use of further fastening means arranged in the first housing part can be dispensed with.

In one example, the fastening means is designed to hold the printed circuit board in a clamping manner.

“Hold in a clamping manner” can be understood to mean that the printed circuit board is held between the housing halves by a support being formed at least in some regions in one housing part and a corresponding hold-down device, which can also be referred to as a “dome,” being arranged in the other housing part, so that the printed circuit board is held between the housing parts after they have been joined. Additionally, holes can also be provided in the printed circuit board to allow easy holding and positioning.

In one example, a third and a fourth lateral wall, which are arranged transversely to the first and second lateral walls are adapted to guide the printed circuit board when displacing the printed circuit board between the first lateral wall and the second lateral wall.

For example, guide grooves for the printed circuit board can be arranged in inner surfaces of the third and fourth lateral walls. Alternatively, the printed circuit board can simply be guided through a precisely fitting gap between the third and fourth lateral walls.

In one example, between the first lateral wall and the second lateral wall at least one guide element is arranged in some regions for displacing the printed circuit board between the first lateral wall and the second lateral wall on a guide track of the guide element.

A guide element can be understood as a web-shaped elevation, a wall projection, a groove, or also a sliding surface, which is arranged, for example, circumferentially on an inner circumference of the first housing element. Alternatively or additionally, the guide element can also be provided as a single web-shaped elevation, wall projection, groove or sliding surface which runs in some regions between the first lateral wall and the second lateral wall. Depending on the application, the fixing domes can also be used as a guide element.

Advantageously, such a guide element also simplifies the introduction of the printed circuit board into the first housing part.

In one example, a third lateral wall and a fourth lateral wall of the first housing part opposite the third lateral wall each adjoin the edge of the first lateral wall and the second lateral wall and run transversely, in particular at right angles, to the first and second lateral walls. In alternative examples, the lateral walls can also run at other angles with respect to one another.

Advantageously, the first housing half can have a rectangular base surface and be intended to receive a rectangular printed circuit board. Alternatively, by using additional curved lateral walls, interior spaces with other dimensions can be created depending on the desired application.

In one example, the second housing part has lateral walls corresponding to the first housing part, for forming a substantially cuboid-shaped electronics housing with base surfaces arranged parallel to one another.

The term “corresponding lateral wall” can be understood to mean that in the second housing part the first lateral wall is higher than the second lateral wall, so that the height of the first housing wall of the first housing and the height of the first housing wall of the second housing are equal to the height of the second housing wall of the first housing and the height of the second housing wall of the second housing. Both housing parts can therefore be wedge-shaped and simply assembled into a cuboid-shaped electronics housing by joining them at the corresponding joint edges. Thus, the housing parts can also be described as being designed to complement one another.

Advantageously, such an electronics housing makes it possible to receive a printed circuit board with electronics arranged thereon in a space-saving manner.

In one example, the joint edge between the third and/or fourth lateral walls of the housing parts extends at least in some regions obliquely, arcuately, jaggedly, step-like or stair-like with respect to a base surface of the housing.

For example, the oblique course of the joint edge can be continuous. The accuracy of fit and tightness can be increased advantageously by a continuous course. Alternatively, the oblique course can also have discontinuities. Advantageously, such discontinuities allow the housing parts to be easily joined together and any transverse/shear forces that may occur can be counteracted by a discontinuous course.

Advantageously, such an at least in some regions non-parallel course of the joint edge between the third and fourth lateral walls can compensate for the relative height difference of the first lateral wall with respect to the second lateral wall relative to the base surface.

In one example, the electronics housing has a sealing element that can be arranged along the joint edge between the first housing part and the second housing part.

For example, the sealing element can have a plastics material and have a geometry corresponding to the course of the joint edge in order to be arranged between the two housing parts when the two housing parts are joined together. The arrangement of a sealing element can advantageously provide protection against foreign bodies or penetrating water.

In one example, the first and/or second housing part comprises an insulating material, in particular a plastics material or a metal, in particular a stainless steel, a zinc die-cast material, or an aluminum material.

For example, the housing parts can be established in one piece or in one piece using a casting process. Advantageously, the housing parts can be made of a material intended for this purpose, depending on the intended use.

In one example, the housing parts are designed to be double-walled at least in some regions and have an overlap region at least in some portions in a region of the joint edge. Advantageously, the joint edge in the housing parts can be designed in two parts at least in some regions, i.e., with an inner joint edge and an outer joint edge, which also run differently in a height direction with respect to the base surface.

This can increase the housing rigidity and also increase air and creepage distances in order to improve the insulation of the electronics arranged in the electronics housing against electrostatic voltages. This can also advantageously allow use in regions with a potential explosion risk.

In one example, the first housing part and the second housing part each have at least one elongated hole, in particular four elongated holes in corner regions of the housing parts, and wherein at least one connecting element, in particular a screw dome, for connecting the first and second housing parts is arranged in the elongated hole of the first housing part or second housing part.

The term “elongated hole” can be understood to mean a cylindrical or oval recess that extends at least in some regions through the material of the housing parts. The recess can also be understood as an opening that is asymmetrical to at least one axis of extension. When the first housing part and the second housing part are joined together, the elongated holes in the housing parts can be designed to correspond to one another, i.e., to be congruent, so that the elongated holes in the housing parts form a common elongated hole in the joined state.

Advantageously, the housing halves can be screwed together by means of screw domes arranged in the elongated holes of the first and/or second housing part in order to firmly connect the housing parts to one another.

In some examples, however, as an alternative to the screw domes, latching elements can be arranged in the elongated holes in order to connect the two housing halves to one another via a latching connection. In examples, the electronics housing can also be arranged on a substrate by means of additional fastening means which extend at least partially through the elongated holes.

In a further example, the electronics housing has a mounting adapter which is adapted to be connectable to the first housing part, wherein the mounting adapter has on a side facing the first housing part at least one locking element corresponding to the elongated hole, in particular four locking elements corresponding to the four elongated holes.

Advantageously, the interconnected housing parts can be fastened to a reference body, such as a wall, a mounting rail, or a socket, via a mounting adapter. The interconnected housing parts can also be connected via the mounting adapter to various holding elements, such as the fastening structures of a switch box or a VESA adapter, as well as to fastening structures of a mounting profile or a pipe/mast, both horizontally and vertically.

In one example, the locking element has a latching and/or screw connection.

Advantageously, the first housing part can be connected to the mounting adapter particularly quickly and easily via a latching connection. Depending on the specific application, the latching connection can be secured using a screw connection to ensure a secure hold. As an alternative to the latching connection, a screw connection can be used to achieve a particularly secure hold.

In one example, the first housing part and the second housing part are designed in the same part, in particular identically.

Advantageously, manufacturing costs can be reduced by using identical housing parts. For example, the housing parts can be reworked to form the electronics housing. This also allows the second housing part to be used as the first housing part and the first housing part to be used as the second housing part.

In one example, the first housing part and the second housing part are interconnected via a joint, in particular a film hinge.

Advantageously, the housing parts can be held together captive via the hinge and can be hinged open. Even if the hinge is destroyed, the housing parts can still be used as intended.

In one example, the first housing part and/or the second housing part has a further opening.

Advantageously, the further opening can be designed in the shape of a window and can be used to arrange a display. Alternatively or additionally, the opening or an additional opening can be used for the installation of actuating elements, such as switches.

In one example, the first housing part and/or the second housing part have corresponding connecting elements on outer surfaces of opposite lateral surfaces in order to be connectable to at least one housing part of another electronics housing.

Advantageously, several similar electronics housings can be interconnected by using such connecting elements.

The invention also relates to a system having an electronics housing as described herein and a printed circuit board which is received in the electronics housing and which has at least one connection element.

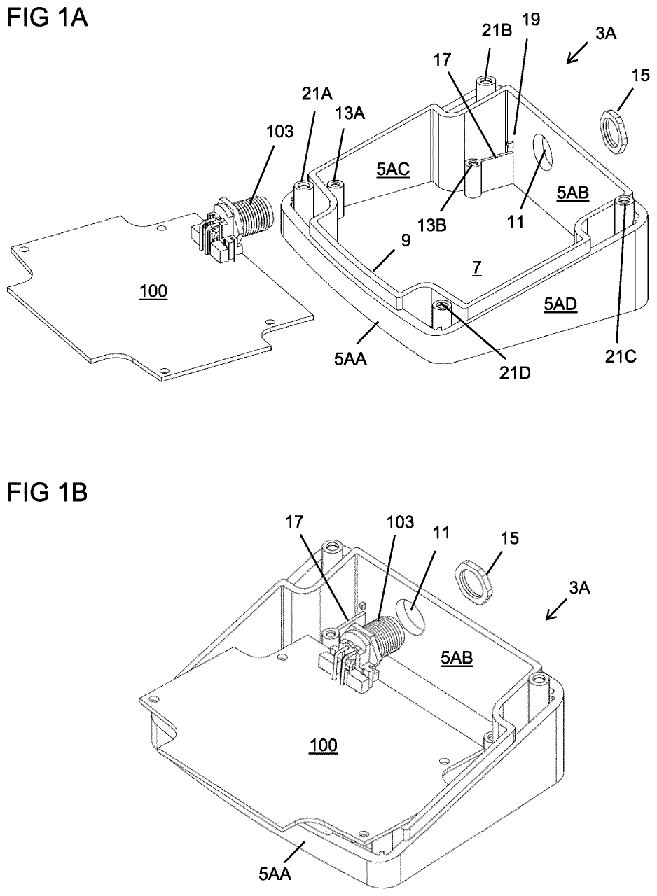

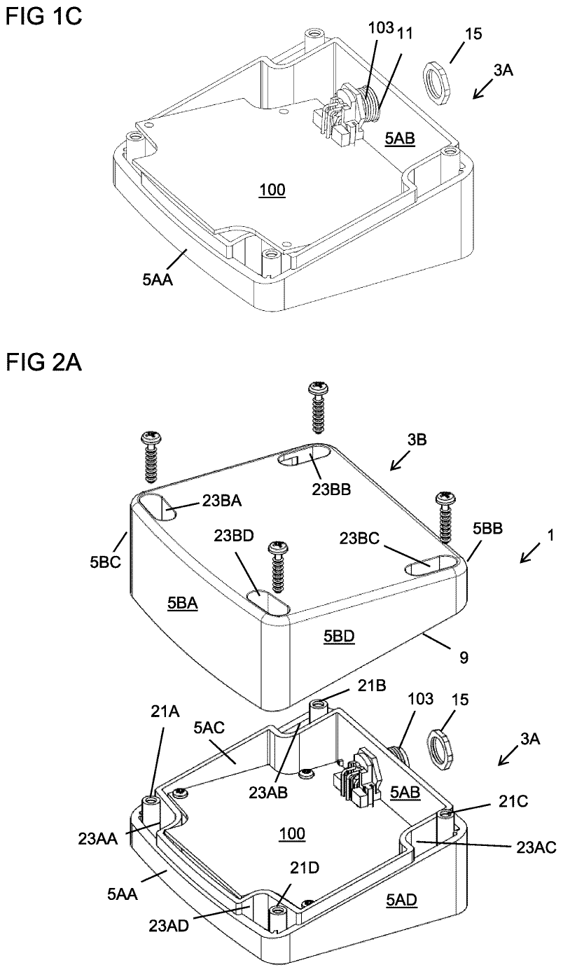

FIG. 1A shows a view of a first housing part 3A and a separately shown printed circuit board 100. The first housing part 3A shown has four lateral walls 5AA-5AD that adjoin one another at the edges and form a housing shell of the first housing part 3A.

Furthermore, the first housing part 3A shown is designed in a shell-like manner and the lateral walls 5AA-5AD are arranged at a right angle to one another on a base surface 7.

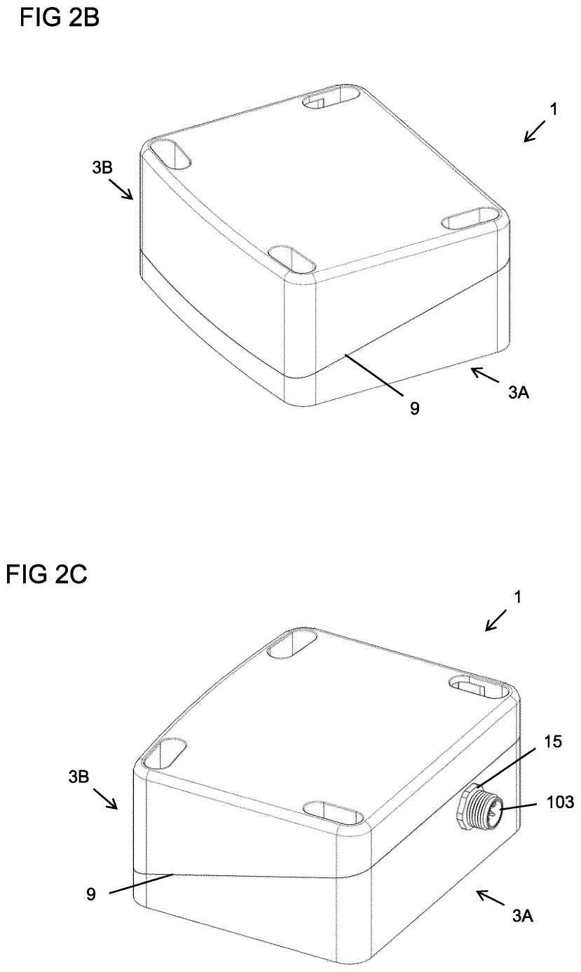

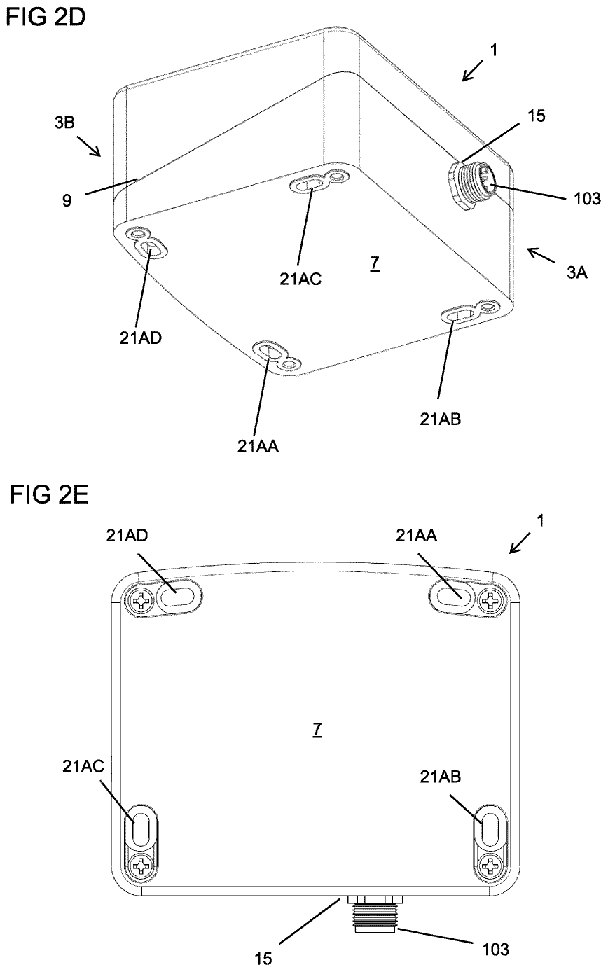

At one end of the lateral walls 5AA-5AD, which is opposite the ends from which the lateral walls 5AA-5AD extend from the base surface 7, the joint edge 9 runs, at which the housing parts can be joined together in a form-fitting and separable manner, as shown in FIGS. 2B-2E . The joint edge 9 has an oblique, non-parallel course in the region of the third and fourth lateral walls 5AC, 5AD in order to compensate for the height difference of the first lateral wall 5AA with respect to the second lateral wall 5AB.

As shown in FIG. 1A, the first lateral wall 5AA of the first housing part 3A is formed lower, at least in one region, than the second lateral wall 5AB of the first housing part 3A opposite the first lateral wall 5AA. This allows the printed circuit board 100 to be easily inserted into the first housing part 3A via the first lateral wall 5AA, as shown below in FIGS. 1B and 1C.

The printed circuit board 100 can thus be inserted into the first housing part 3A substantially horizontally to the base surface 7 of the first housing part 3A over the joint edge 9 of the first lateral wall 5AA up to the second lateral wall 5AB.

It is also shown that the second housing wall 5AB has an opening 11, which is shown as a round through opening in the material of the second housing wall 5AB and is completely surrounded by the material of the second housing wall 5AB. The connection element 103 arranged on the printed circuit board 100, shown as an electrical socket, can thus be introduced into the opening 11 via the first lateral wall 5AA when the printed circuit board 100 is inserted (as shown in FIGS. 1B and 1C) in order to be able to be electrically contacted from outside the electronics housing. In embodiments, a plurality of connection elements can be arranged on the printed circuit board and each inserted into a corresponding opening in the first lateral wall.

Furthermore, FIG. 1A shows that the first housing part 3A has fastening means 13A, 13B for fastening the printed circuit board 100 in the first housing part 3A. In the embodiment shown, the fastening means 13A, 13B is represented as a plurality of screw domes, wherein only two fastening means 13A, 13B are visible in FIG. 1A. The screw domes extend in corner regions of the first housing part 3A from the base surface 7, parallel to the lateral walls 5AA-5AD, wherein in the inserted state, as shown in FIG. 2A, regions of the printed circuit board 100 rest on the screw domes 3A, 3B. After the printed circuit board has been introduced, screws are inserted through the openings provided in the printed circuit board 100 in order to fix the printed circuit board 100.

Also shown in FIG. 1A is a screw connection 15 which is adapted to fix the connection element 103 after it has been inserted into the opening 11. As shown, the connection element 103 has an external thread onto which the screw connection 13 can be screwed in order to fix the connection element 103 and the printed circuit board 100 connected thereto.

It is also shown that between the first lateral wall 5AA and the second lateral wall 5AB one guide element 17 is arranged at least in some regions for displacing the printed circuit board 100 between the first lateral wall 5AA and the second lateral wall 5AB on a guide track of the guide element 17. Furthermore, a holding means 19 is shown in FIG. 1A, which is arranged as a projection on the second lateral wall 5AB above the guide element 17. In the inserted state, which is shown in FIG. 2A, the printed circuit board 100 is held between the guide element 17 and the holding means 19.

FIG. 1A also shows that the first housing part 3A is designed to be double-walled, at least in some regions.

In addition, the first housing part 3A further comprises connecting elements 21A-21D, which are designed as screw domes, for connecting the shown first housing part 3A to a second housing part, as shown in FIGS. 2A-2E.

FIG. 1B shows the first housing part 3A shown in FIG. 1A and a printed circuit board 100. FIG. 1B shows a state in which the printed circuit board 100 is inserted into the housing 3A. For this purpose, the printed circuit board 100 is pushed over the low first lateral wall 5AA of the first housing part 3A. In FIG. 1C, the printed circuit board 100 has been inserted further in the direction of the first lateral wall 5AA, so that the connection element 103 is already located in the opening 11. In FIG. 1C, it is shown that the printed circuit board 100 is not pushed completely horizontally to the base surface over the first lateral wall 5AA, but slightly tilted at an angle of usually 5° to 15° toward the base surface of the first housing part 3A. The printed circuit board 100 rests on the guide element 17 shown in FIGS. 1A and 1B and is moved further on the guide element 17 in the direction of the second lateral wall 5AB.

FIG. 2A shows a view of the electronics housing 1 with the printed circuit board 100 arranged therein according to the embodiment of the invention previously shown in FIGS. 1A-1C .

In the illustration shown in FIG. 2A, the printed circuit board 100 rests on the fastening means 13A, 13B shown as screw domes in FIGS. 1A and 1B. Screws are inserted through the printed circuit board 100 through openings in the printed circuit board 100 in order to fix the printed circuit board 100 in the first housing part 3A between the lateral walls 5AA-5AD.

As shown, the first housing part 3A and the second housing part 3B are designed to be substantially complementary to one another in order to meet on the joint edge 9 when joined together. The two housing parts 3A, 3B shown are wedge-shaped and can be assembled to form a cuboid-shaped electronics housing 1, as shown in the following figures.

In the embodiment shown, the first housing part 3A and the second housing part 3B each have four elongated holes 23AA-23BD in the corner regions of the housing parts 3A, 3B. Connecting elements 21A-21D, shown as screw domes, for connecting the first and second housing parts 3A, 3B, are arranged in the elongated holes 23AA-23AD of the first housing part 3A. The shown elongated holes 23AA-23BD run correspondingly to one another, so that the elongated holes in the housing parts 3A, 3B form a common elongated hole in the assembled state.

In FIGS. 2B and 2C, the electronics housing 1 shown in FIG. 2A is shown in the assembled state. The housing parts 3A, 3B are joined together along the joint edge 9 in a form-fitting manner and can be separated from one another.

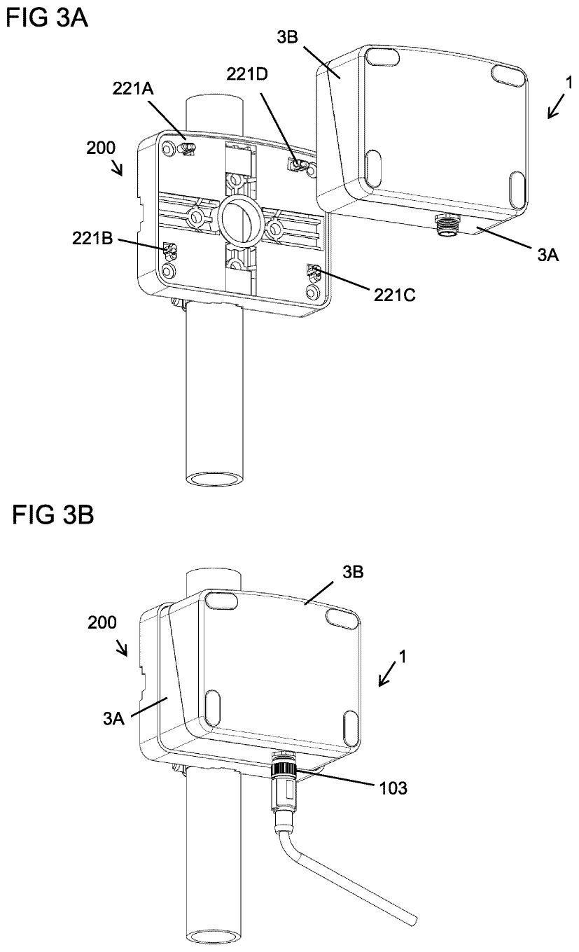

FIGS. 2D and 2E show further views of the electronics housing 1 shown in FIGS. 2A-2C. FIGS. 2D and 2E show views of the outside of the base surface 7 of the first housing part 3A, with which the electronics housing 1 can either be mounted directly on a substrate or mounted on a mounting adapter. For this purpose, the mounting adapter can have locking elements that correspond to the elongated holes 21AA-21AD in order to fasten the electronics housing 1 on the mounting adapter, as shown in the following FIGS. 3A, 3B.

FIG. 3A shows a view of the first and second housing parts 3A, 3B and a mounting adapter 200 according to an embodiment of the invention. The mounting adapter 200 is here, for example, fastened to a rod and is designed to be connectable to the first housing part 3A. For this purpose, locking elements 221A-221D are arranged on the mounting adapter 200, which correspond to the ends of the elongated holes 21AA-21AD shown in FIG. 2E in order to establish a latching connection when the first housing part 3A is placed on the mounting adapter 200.

FIG. 3B shows a view in which the first housing part 3A is placed on the mounting adapter 200. It is also shown that the connection element 103 is connected to a corresponding connection cable.

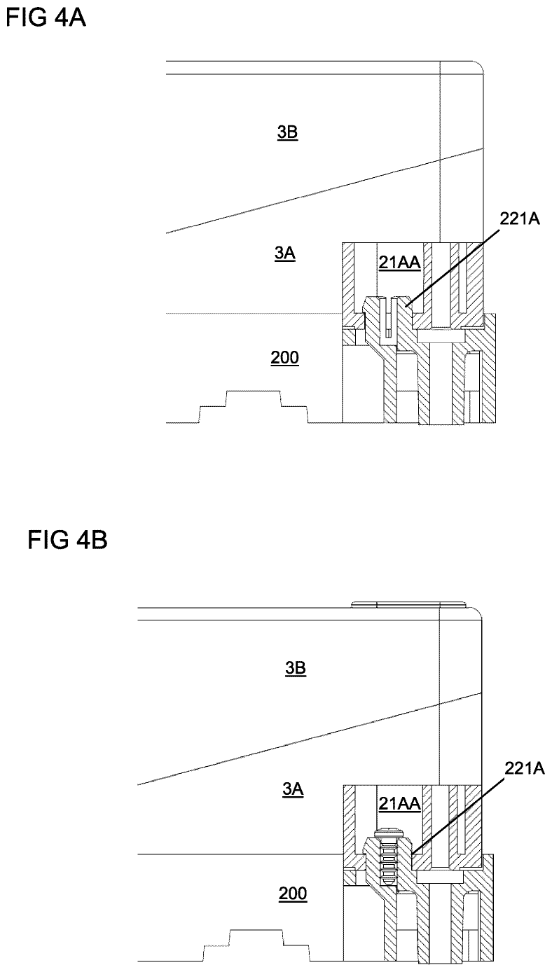

FIG. 4A shows a sectional view through a locking element 221A of the mounting adapter 200 inserted into an elongated hole 21AA of the first housing half 3A. As shown, the locking element 221A forms a latching connection with a region of the elongated hole 21AA. FIG. 4B shows the view from FIG. 4A with an additional screw inserted into the locking element 221A to prevent accidental unlatching of the latching connection.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1 Electronics housing
3A, 3B Housing part
5AA-5BD Lateral walls
7 Base surface
9 Joint edge
11 Opening
13A-13D, 15 Fastening means
17 Guide element
19 Holding means
21A-21D Connecting elements
23AA-23BD Elongated holes
100 Printed circuit board
103 Connection element
200 Mounting adapter
221A-221D Locking elements

1. An electronics housing for receiving a printed circuit board, comprising:
a first housing part; and
a second housing part,
wherein the first and second housing parts are joinable together along a joint edge in a form-fitting and separable manner, and the first and second housing parts have lateral walls that adjoin one another at edges and form a housing shell,
wherein
a first lateral wall of the first housing part is lower than a second lateral wall of the first housing part in at least one region, the second lateral wall lying opposite the first lateral wall, in order to insert the printed circuit board into the first housing part via the first lateral wall, and
wherein the second lateral wall has at least one opening for introducing a connection element connected to the printed circuit board into the at least one opening.

2. The electronics housing of claim 1, wherein the first housing part has fastening means configured to fasten the printed circuit board in the first housing part.

3. The electronics housing of claim 2, wherein the fastening means comprise at least one screw dome, latching means configured to form a latching connection for fastening the printed circuit board in the first housing part, and a screw connection configured to hold the connection element and the printed circuit board connected thereto in the opening.

4. The electronics housing of claim 2, wherein the fastening means is configured to hold the printed circuit board in a clamping manner.

5. The electronics housing of claim 1, further comprising:
a third lateral wall and a fourth lateral wall, which are arranged transversely to the first lateral wall and the second lateral wall, the third and fourth lateral walls being configured to guide the printed circuit board when displacing the printed circuit board between the first lateral wall and the second lateral wall.

6. The electronics housing of claim 1, wherein, between the first lateral wall and the second lateral wall, at least one guide element is arranged at least in some regions so as to displace the printed circuit board between the first lateral wall and the second lateral wall on a guide track of the guide element.

7. The electronics housing of claim 1, wherein the second housing part has lateral walls corresponding to the first housing part, so as to form a substantially cuboid-shaped electronics housing with base surfaces arranged parallel to one another.

8. The electronics housing of claim 5, wherein a joint edge between the third lateral wall and/or fourth lateral wall extends at least in some regions at least one of obliquely, arcuately, jaggedly, step-like, or stair-like with respect to a base surface of the electronics housing.

9. The electronics housing of claim 1, further comprising:
a sealing element arrangeable along the joint edge between the first housing part and the second housing part.

10. The electronics housing of claim 1, wherein the first housing part and/or second housing part comprises an insulating material comprising a plastics material or a metal comprising at least one of a stainless steel, a zinc die-cast material, or an aluminum material.

11. The electronics housing of claim 1, wherein the housing parts are double-walled at least in some regions and have an overlap region at least in some portions in a region of the joint edge.

12. The electronics housing of claim 1, wherein the first housing part and the second housing part each have at least one elongated hole, and
wherein at least one connecting element comprising a screw dome configured to connect the first housing part and second housing part is arranged in the at least one elongated hole of the first housing part or second housing part.

13. The electronics housing of claim 12, further comprising:
a mounting adapter configured to be connectable to the first housing part,
wherein the mounting adapter has on a side thereof facing the first housing part at least one locking element corresponding to the at least one elongated hole.

14. The electronics housing of claim 13, wherein the locking element has a latching connection and/or screw connection.

15. A system having an electronics housing of claim 1, and a printed circuit board which is received in the electronics housing and which has at least one connection element.

16. The electronics housing of claim 12, wherein the at least one elongated hole comprises four elongated holes in corner regions of the housing parts.

17. The electronics housing of claim 13, wherein the at least one locking element comprises four locking elements,
wherein the at least one elongated hole comprises four elongated holes, and
wherein the four locking elements correspond to the four elongated holes.
